(19) United States
(12) Patent Application Publication
(10) Pub. No.: US 2010/0200896 A1
(43) Pub. Date: Aug. 12, 2010

(54) EMBEDDED STRESS ELEMENTS ON SURFACE THIN DIRECT SILICON BOND SUBSTRATES

(75) Inventors: Thomas N. Adam, Slingerlands, NY (US); Jinghong Li, Poughquag, NY (US); Thomas A. Wallner, Pleasant Valley, NY (US); Haizhou Yin, Poughkeepsie, NY (US)

Correspondence Address: INTERNATIONAL BUSINESS MACHINES CORPORATION;DEPT. 18G, BLDG. 321-482, 2070 ROUTE 52, HOPEWELL JUNCTION, NY, 12533, US

(73) Assignee: INTERNATIONAL BUSINESS MACHINES CORPORATION, Armonk, NY (US)

(21) Appl. No.: 12/367,561

(22) Filed: Feb. 9, 2009

(51) Int. Cl. H01L 29/04; H01L 21/20; H01L 29/161

(52) U.S. Cl. 257/255; 438/478; 257/616; 257/E21.09; 257/E29.084; 257/E29.004

(57) ABSTRACT

A method for growing an epitaxial layer on a substrate wherein the substrate includes a surface having a Miller index of (110) for the beneficial properties. The method comprises using a direct silicon bonded wafer with a substrate having a first Miller index and a surface having a second Miller index. An element such as a gate for a PFET may be deposited onto the surface. The area not under the gate may then be etched away to expose the substrate. An epitaxial layer may then be grown on the surface providing optimal growth patterns. The Miller index of the substrate may be (100). In an alternative embodiment the surface may have a Miller index of (100) and the surface is etched where an element such as a gate for a PFET may be placed.

### BACKGROUND

The use of Silicon Germanium (SiGe) as a semiconductor was championed by Bernie Meyerson, an IBM fellow. SiGe is manufactured on silicon wafers using conventional silicon processing toolsets. SiGe processes achieve costs similar to those of silicon CMOS manufacturing and are lower than those of other heterojunction technologies such as gallium arsenide.

SiGe allows CMOS logic to be integrated with heterojunction bipolar transistors, making it suitable for mixed-signal circuits. Heterojunction bipolar transistors have higher forward gain and lower reverse gain than traditional homojunction bipolar transistors. This translates into better low current and high frequency performance. Being a heterojunction technology with an adjustable band gap, the SiGe offers the opportunity for more flexible band gap tuning than silicon-only technology.

Silicon Germanium-on-insulator (SGOI) is a technology analogous to the Silicon-On-Insulator (SOI) technology currently employed in computer chips. SGOI increases the speed of the transistors inside microchips by straining the crystal lattice under the MOS transistor gate, resulting in improved electron mobility and higher drive currents. SiGe MOSFETs can also provide lower junction leakage due to the lower band gap value of SiGe.

All lattice planes and lattice directions are described by a mathematical description known as a Miller Index. This allows the specification, investigation, and discussion of specific planes and directions of a crystal. In the cubic lattice system, the direction [hk1] defines a vector direction normal to surface of a particular plane or facet.

The growth rate for SiGe is fastest of a Miller index of (100). A Miller index of (110) the growth rate is slower than a Miller index of (100), however, it is faster than for a Miller index of (111).

Growing traditional SiGe stress elements on (110) surface wafers is a well documented challenge. The inventors have identified that issues exist due to the fast growth plane (100) being at a 45 degree angle to the wafer surface. Since the fast growth plane is at a 45 degree angle, the growth will be uneven between elements on the wafer. It is the desire of the inventors to provide a means for ensuring that the wafer growth is consistent across the wafers.

### SUMMARY

According to an embodiment of the present invention is to provide methods to grow SiGe. The inventors have determined that by utilizing a surface with a Miller index of (110) with a direct silicon bond substrate having an index of (100). A wafer may be ordered with a surface of (110) and the substrate of (100). Features may be formed on the surface of the wafer, for example gates may be formed on the surface where the (110) surface may be optimal for the formation of a gate. Once the gates or other element has been formed on the surface, the wafer is etched to remove the surface material until the substrate with the (100) miller index material is exposed. An epitaxial layer of SiGe or another material such as SiC is then formed on the wafer and due to the substrate having a (100) Miller index the growth is perpendicular to the wafer surface.

### BRIEF DESCRIPTION OF THE SEVERAL VIEWS OF THE DRAWINGS

FIG. 1 is an example representing a prior art application of silicon germanium.

FIG. 2 illustrates an example of a prior art application of SiGe.

FIG. 3 illustrates a wafer with a (110) surface and a (100) substrate according to an embodiment of the invention.

FIG. 4 illustrates an example of a SiGe epitaxial layer formed on a wafer with a (110) surface and a (100) substrate according to an embodiment of the invention.

FIG. 5 is a flow diagram of a method for growing SiGe on a wafer.

FIG. 6 illustrates an alternative embodiment of the invention.

### DETAILED DESCRIPTION

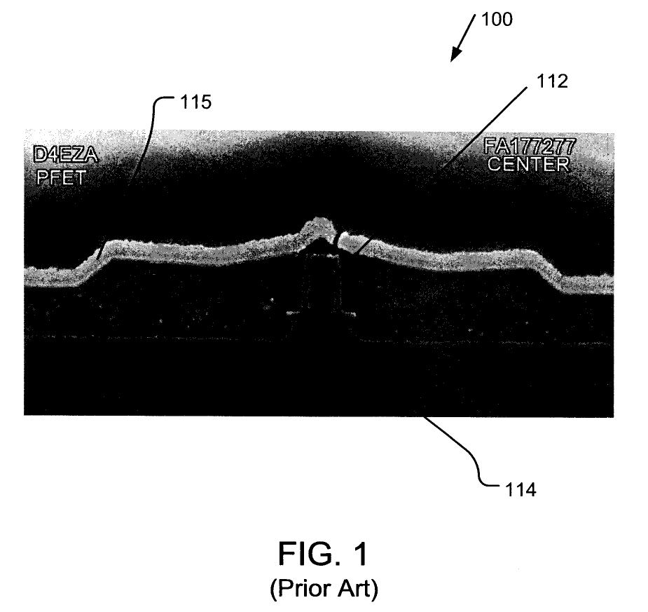

With reference now to FIG. 1 is an example representing a prior art application of SiGe. FIG. 1. illustrates an application of SiGe to a wafer having a Miller index of (110). The index of (110) was utilized due to the beneficial properties when forming the gate 112 on the (110) index silicon 100. A substrate 114 is processed with a SiGe epitaxial layer 116. A shoulder 115 is produced due to the use of a (110) substrate 114. The (110) substrate is utilized as it promotes high mobility for PFETS. In addition the SiGe may be doped with Boron and or Carbon (SIGE:B, SIGE:C, or SIGE:B:C)

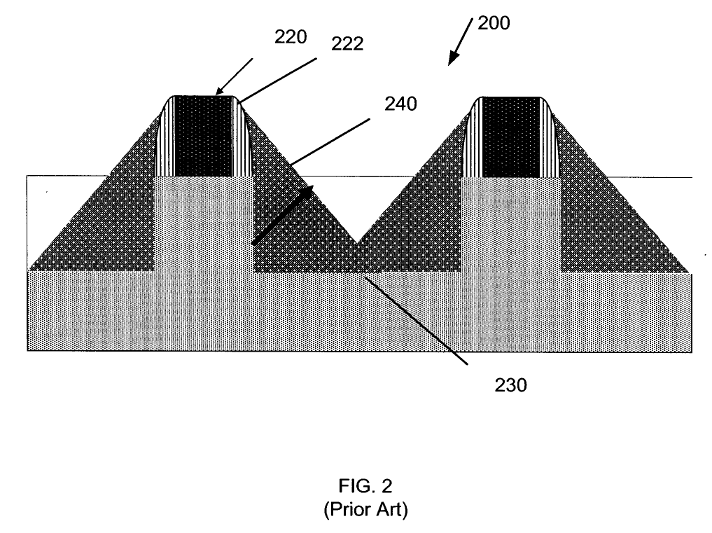

FIG. 2 illustrates an example of a prior art application of SiGe. A substrate 210 is utilized with a Miller index (110). Gates 220 is formed with spacers 222 on substrate 210. Once the gate 220 is formed and the spacer 222 is formed the substrate 210 is etched away forming the source drain areas 230. An epitaxial layer of SiGe 240 is formed in the source drain 230. Because the substrate 210 has a Miller index of(110), the SiGe 240 will grow at a 45 degree angle as illustrated. This prevents the ideal growth pattern from forming.

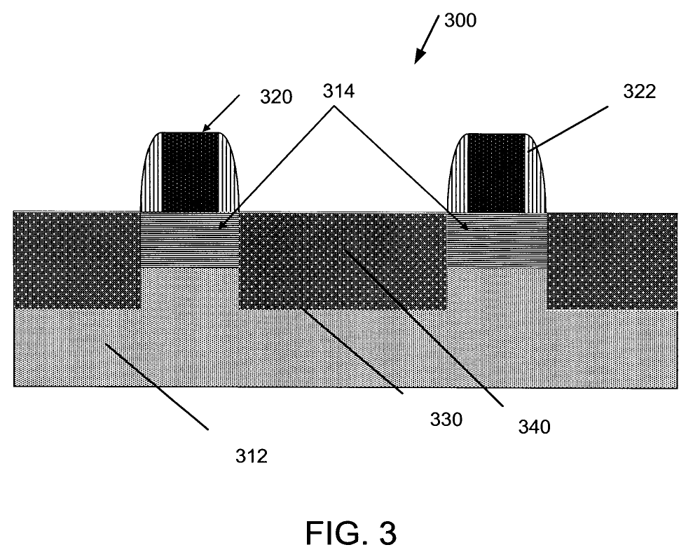

FIG. 3 illustrates a wafer with a (110) surface bonded directly to a (100) surface substrate according to an embodiment of the invention. The wafer 300 is formed with a direct silicon bond which allows for a surface 314 with a Miller Index of (110) and a substrate with an index of (100). The surface 314 in one embodiment should be at least 50 angstroms thick. Gates 320 are formed with spacers 322 on the surface 314. Once the features are formed the wafer 300 is etched to form the source drain 330. Source drains 330 may be from 100 to 1000 angstroms thick. The source drain 330 is etched such that the substrate 312 is exposed. While FIG. 3 illustrates an etch into the substrate 312, the etch needs to only expose the substrate 312. An epitaxial layer of SiGe 340 is then formed on the substrate 312.

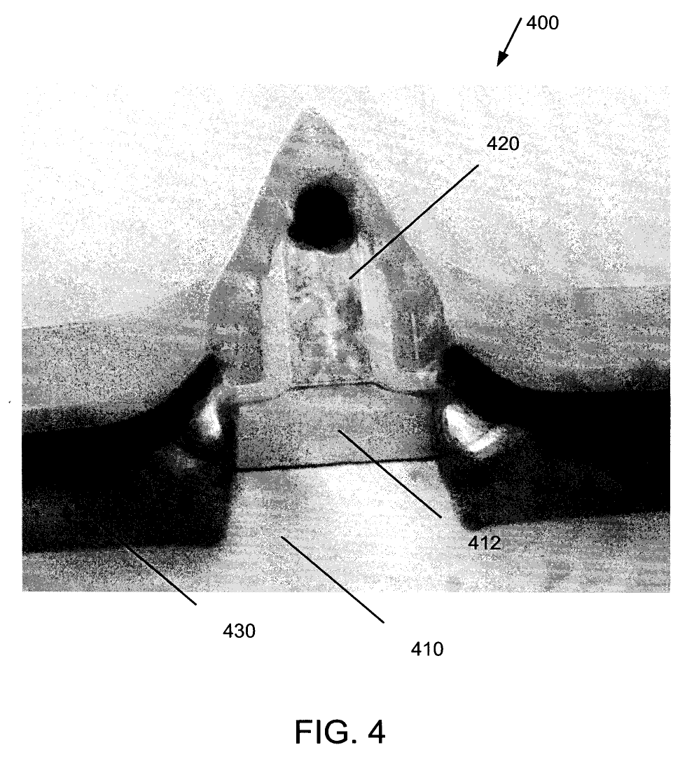

FIG. 4 illustrates an example of a SiGe epitaxial layer formed on a wafer with a (110) surface bonded directly to a (100) surface substrate according to an embodiment of the invention. While SiGe is shown, SiC (Silicon Carbon) for NFET devices. In addition the SiGe may be doped with Boron and or Carbon (SIGE:B, SIGE:C, or SIGE:B:C) The substrate 410 is illustrated for wafer 400. Surface 412 is etched away except under gate 420. As can be seen the growth of the SiGe layer 430 is more uniform than that seen in FIG. 1.

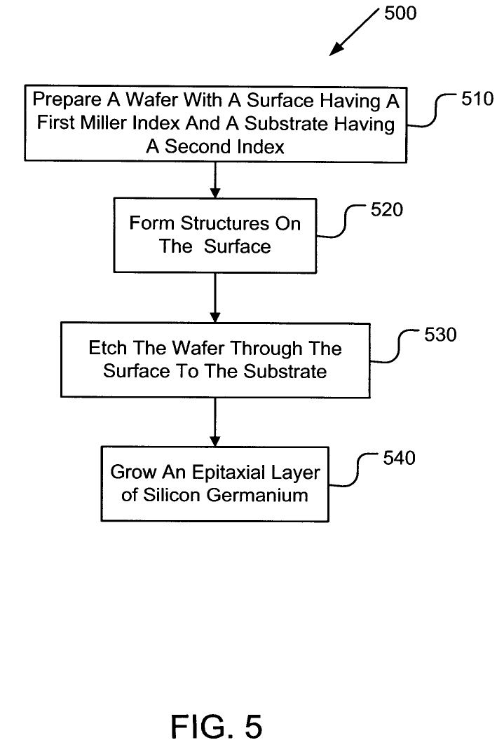

FIG. 5 is a flow diagram of a method 500 for growing SiGe on a wafer. Activity 510 may be to prepare a wafer with a surface having a first Miller index and a substrate having a second Miller index. The first Miller index may be (110) and the second Miller index may be (100). Activity 520 may be to form structures on the surface. These structures may be a gate for a PFET. Activity 530 is to etch the wafer through the surface to the substrate. The etch need not be into the substrate but must expose the substrate before growing the epitaxial layer of SiGe. Activity 540 may be to grow an epitaxial layer of SiGe on the substrate.

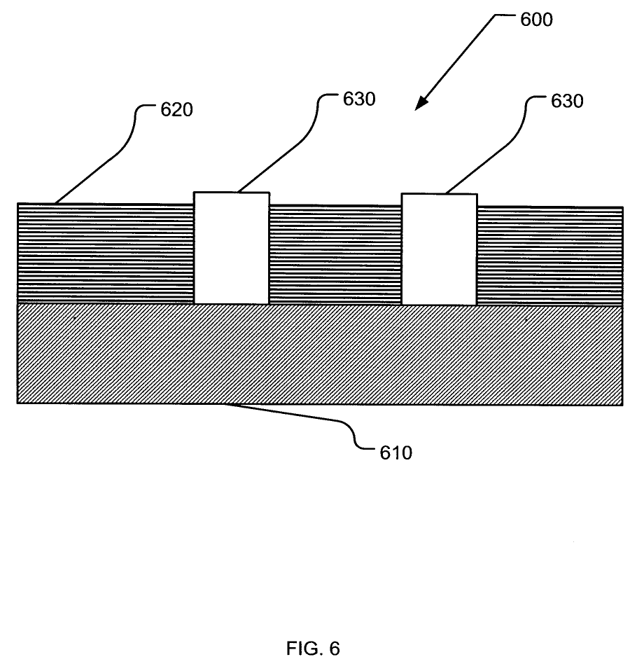

FIG. 6 illustrates an alternative embodiment of the invention. In a case where the direct silicon bond has a substrate 610 with a Miller index of (110) and a surface 620 of (100). A gate 630 may be formed by etching away the surface 620 through to the substrate 610. The gate 630 is then deposited so that it is in contact with the substrate 610 and NFETS may be formed on the surface without the detrimental performance effects of the (110) substrate.

The terminology used herein is for the purpose of describing particular embodiments only and is not intended to be limiting of the invention. As used herein, the singular forms “a”, “an” and “the” are intended to include the plural forms as well, unless the context clearly indicates otherwise. It will be further understood that the terms “comprises” and/or “comprising,” when used in this specification, specify the presence of stated features, integers, steps, operations, elements, and/or components, but do not preclude the presence or addition of one or more other features, integers, steps, operations, elements, components, and/or groups thereof.

The corresponding structures, materials, acts, and equivalents of all means or step plus function elements in the claims below are intended to include any structure, material, or act for performing the function in combination with other claimed elements as specifically claimed. The description of the present invention has been presented for purposes of illustration and description, but is not intended to be exhaustive or limited to the invention in the form disclosed. Many modifications and variations will be apparent to those of ordinary skill in the art without departing from the scope and spirit of the invention. The embodiment was chosen and described in order to best explain the principles of the invention and the practical application, and to enable others of ordinary skill in the art to understand the invention for various embodiments with various modifications as are suited to the particular use contemplated.

What is claimed is:

1. A Method comprising the steps:
a. growing an element on a surface of a direct silicon bonded wafer, the wafer having a surface with a first Miller index and a substrate with a second Miller index;
b. etching away the surface from the wafer to expose the substrate; and
c. growing an epitaxial layer on the substrate.

2. The method of claim 1, wherein the substrate has a Miller index of (100).

3. The method of claim 1, wherein the surface has a Miller index of (110).

4. The method of claim 2, wherein the surface has a Miller index of (110).

5. The method of claim 1, wherein the epitaxial layer is Silicon Germanium.

6. The method of claim 5, wherein the substrate has a Miller index of (100).

7. The method of claim 6, wherein the surface has a Miller index of (110).

8. An apparatus comprising:
a. a direct silicon wafer having a first layer with a first Miller index and a second layer having a second Miller index;
b. an element formed on the second layer; and
c. an epitaxial layer grown in an etched portion of the wafer, wherein the etch of the second layer exposes the first layer.

9. The apparatus of claim 8, wherein the first Miller index is (100) and the second miller index is (110).

10. The apparatus of claim 9, wherein the element is a gate for a PFET.

11. The apparatus of claim 9, wherein the first Miller index is (100) and the second Miller index is (110).

12. The apparatus of claim 10, wherein the first Miller index is (100) and the second Miller index is (110).

13. The apparatus of claim 12, wherein the epitaxial layer is Silicon Germanium.

14. A method comprising:
a. etching a surface of a direct silicon bonded wafer to expose a substrate, wherein the surface has a first Miller index and the a substrate has a second Miller index; and
b. growing an element on the etched area.

15. The method of claim 14, wherein the first Miller index is (100).

16. The method of claim 15, wherein the second Miller index is (110).
